(19) United States
(12) Patent Application Publication
(10) Pub. No.: US 2008/0210290 A1
(43) Pub. Date: Sep. 4, 2008

(54) Plasma inside vapor deposition apparatus and method for making multi-junction silicon thin film solar cell modules and panels

(76) Inventors: Dau Wu, Fallbrook, CA (US); Charles DeLuca, South Windsor, CT (US)

Correspondence Address: PATTON BOGGS LLP, 2550 M STREET NW, WASHINGTON, DC, 20037-1350, US

(21) Appl. No.: 12/081,337

(22) Filed: Apr. 15, 2008

Related U.S. Application Data
(63) Continuation-in-part of application No. 11/783,969, filed on Apr. 13, 2007.
(60) Provisional application No. 60/791,883, filed on Apr. 14, 2006.
(60) Provisional application No. 60/815,575, filed on Jun. 22, 2006.

(51) Int. Cl. H01L 31/042; C23C 16/44; H05H 1/24

(52) U.S. Cl. 136/244; 118/723 R; 427/578; 427/576

(57) ABSTRACT

A plasma inside vapor deposition apparatus for making silicon thin film solar cell modules including means for supporting a substrate, the substrate having an outer surface and an inner surface; plasma torch means located proximal to the inner surface for depositing at least one thin film layer on the inner surface of the substrate, the plasma torch means located a distance from the substrate; and means for supplying reagent chemicals to the plasma torch means, wherein the at least one thin film layer form the silicon thin film solar cell modules.

### CROSS-REFERENCES TO RELATED APPLICATIONS

This application is a continuation-in-part of prior U.S. patent application Ser. No. 11/783,969, filed Apr. 13, 2007, which claims the benefit of U.S. Provisional Patent Application Nos. 60/791,883, filed Apr. 14, 2006 and 60/815,575, filed Jun. 22, 2006. The entireties of these applications are incorporated herein by reference.

### FIELD OF THE INVENTION

The present invention relates to a vapor deposition apparatus, and more particularly to a vapor deposition apparatus and method for making silicon thin film solar cell modules and panels.

### Problem

As oil prices have continued to increase and other energy sources remain limited, there also is increasing pressure on global warming from the emissions of burning fossil fuel. There is a need to find and use alternative energy sources, such as solar energy because it is free and does not generate carbon dioxide gas. To that end, many nations are increasing their investment in safe and reliable long-term sources of power, particularly “green” or “clean” energy sources. Nonetheless, while the solar cell, also known as a photovoltaic cell or modules, has been developed for many years, it had very limited usage because the cost of manufacturing these cells or modules is still high, making it difficult to compete with energy generated by fossil fuel.

Presently, the single crystal silicon solar cell has the best energy conversion efficiency, but it also has the highest manufacture cost. Alternatively, thin-film silicon while it does not have the same high efficiency of a single crystal cell, it is much cheaper to produce. Therefore, it has the potential for low cost photovoltaic power generation. Other types of thin-film materials such as copper indium gallium diselenide (“CIGS”) also showed promising results with efficiencies approaching that or single crystal silicon, at a lower cost, but still not low enough to compete effectively with fossil fuel.

Part of the reason for the manufacturing expense is that the deposition rates of these processes are low and time consuming. For example, the typical process of plasma glow discharge of silane in the presence of a high concentration of hydrogen gas to form the desired silicon layer achieves a deposition rate of approximately 20 A/s or 0.12 microns/minute. For another example, the typical plasma chemical vapor deposition (“CVD”) method for forming high quality i-type silicon layer achieves a reported deposition rate of approximately 15 A/s or 0.09 microns/minute. In yet another example, the typical chemical vapor transport (“CVT”) method, which uses iodine vapor as a transport medium to deposit polycrystalline silicon, achieved film growth rates up to approximately 3 microns/minute. The best reported deposition rate for Plasma-Enhanced Chemical Vapor Deposition (“PECVD”) is approximately 5 A/s.

Similar to silicon solar cell technologies, efforts have been made to manufacture CIGS type solar cells using different techniques. In one attempt, CIGS type solar cells are manufactured in a two-stage process using various precursor structures, which is known as the selenization technology. Attempts have been made to improve on the selenization technology. In one such attempt, a two-stage process using the magnetron sputtering technique with a conveyor system to make a thin film is known. In another attempt, a vapor-phase recrystallization process is used to make CIGS films. The recrystallization process was used as the second step of the process and it replaced the selenization process as taught by previous arts. In yet another attempt, CIGS film was manufactured using an electrochemical deposition in a solution that was followed by physical vapor deposition. This technology produced a CIGS type solar cell with an overall conversion efficiency of 13.6%.

In addition to the efforts to efficiently manufacture the types of solar cells mentioned above, additional efforts have been expended to efficiently manufacture other types of solar cells, such as multi-junction solar cells. These types of solar cells have the construction of multiple layers with different materials. The different materials have different bandgaps and they will absorb various wavelengths of the solar energy. Thus, these types of solar cells cover a broader solar spectrum and may improve the efficiency of the solar cell. Some efforts have been expended to efficiently produce these types of solar cells. In one such effort, multi-junction solar cells are manufactured with amorphous silicon and copper indium diselenide (“CIS”) and their alloys. However, this manufacturing process is very complicated and needs different kinds of equipment, thus making it expensive to produce these types of solar cells. Some examples for producing layers of CIS or CIGS include depositing these layers by way of solution growth, sputtering, or evaporation. Also, layers of silicon are deposited byway of enhanced plasma chemical vapor deposition.

Furthermore, in addition to slow deposition rates, another slow process step found commonly in the manufacture of solar cells involves the incorporation of p-type and n-type dopants to form the p-n junction of the semiconductor material. This step is normally done in extremely slow diffusion furnaces after the thin-film layer has already been deposited, thus further slowing down the overall process of efficiently producing solar cells.

In addition, with regard to the process of making CIGS thin films, the process usually uses two or more stages. The purpose for the additional steps of the process is to deposit or adjust these elements to achieve the desired or optimum composition ratios and phase structure of the CIGS thin films. In the first step, various techniques have been used for build-up the required thickness of film with the concentration ratios being relatively close to the designed value. The combination of these steps inhibits an efficient manufacturing process for making CIGS thin films.

Additionally, multiple-junction solar cells have been contemplated. For example, J. Yang et al. reported at the 1^{st} World Conference on Photovoltaic Energy Conversion (1994) with the title of “Progress in Triple-Junction Amorphous Silicon-Based Alloy Solar Cells and Modules Using Hydrogen Dilution.” Recently, X. Deng also reported a triple-junction photovoltaic cell structure at the 31^{st} IEEE Photovoltaic Specialist Conference (2005), titled, “Optimization of a SiGe-based triple, tandem and single-junction solar cells.” To deposit these semiconductor thin film layers, Deng used capacitive coupled plasma enhanced chemical vapor deposition (“PECVD”) process where the completed system also included magnetron sputtering units for back reflection and transparent conductive metal oxide (“TCO”) layers. This system consists of four PECVD chambers, four sputter chambers and one load-lock chamber. It can make a deposition tube 4″×4″ triple-junction solar cells without vacuum break.

Information relevant to attempts to address these problems can be found in the U.S. Pat. Nos. 5,646,050 issued Jul. 8, 1997 to Li, et al.; 5,942,049 issued Aug. 24, 1999 to Li, et al.; 6,100,466 issued Aug. 8, 2000 to Nishimoto; 6,214,706 issued Apr. 10, 2001 to Madan, et al.; 6,281,098 issued Aug. 28, 2001 to Wang, et al.; 5,141,564 issued Aug. 25, 1992 to Chen, et al.; 4,798,660 issued Jan. 17, 1989 to Ermer, et al.; 4,915,745 issued Apr. 10, 1990 to Pollock et al.: 6,048,442 issued Apr. 11, 2000 to Kushiya, et al.; 6,258,620 issued Jul. 10, 2001 to Morel, et al.; 6,518,086 issued Feb. 11, 2003 to Beck et al.; 5,045,409 issued Sep. 3, 1991 to Eberspacker, et al.; 5,356,839 issued Oct. 18, 1994 to Tuttle, et al.; 5,441,897 issued Aug. 15, 1995 to Noufi, et al.; 5,436,204 issued Jul. 25, 1995 to Albin, et al.; 5,730,852 issued Mar. 24, 1998 to Bhattacharya, et al.; 5,804,054 issued Sep. 8, 1998 to Bhattacharya, et al. 5,871,630 issued Feb. 16, 1999 to Bhattacharya, et al.; 5,976,614 issued Nov. 2, 1999 to Bhattacharya, et al.; 6,121,541 issued Sep. 19, 2000 to Arya; 6,368,892 issued Apr. 9, 2002 to Arya; 3,993,533 issued Nov. 23, 1976 to Milnes et al.; 4,891,074 issued Jan. 2, 1990 to Ovshinsky; 5,231,048 issued Jul. 27, 1993 to Guha et al.; 6,613,974 issued Sep. 2, 2003 to Husher, and 6,670,544 issued Dec. 30, 2003 to Kibbel et al.

### Solution

The above-described problems are solved and a technical advance achieved by the plasma inside vapor deposition apparatus and method for making multi-junction silicon thin film solar cell modules and panels (“apparatus for making solar cell modules and panels”) disclosed in this application. The novel apparatus provides a measurably higher deposition rate, thus leading to a much lower manufacturing cost. The apparatus for making solar cell modules and panels provides for the deposition of thin film layers on a substrate, which may be a rotating tubular member or supported by a rotating tubular member.

The apparatus for making solar cell modules and panels provides for depositing thin films on the inner wall of a tubular member, which automatically provides an isolated environment for the reactants and products to form a thin film on the inner wall of the tubular member. The apparatus for making solar cell modules and panels provides for a simpler exhaust system for making solar cell modules and panels than previous designs. The apparatus for making solar cell modules and panels uses an induction coupled plasma torch to make the thin film solar cell modules and panels. In addition to its higher deposition rate, the apparatus for making solar cell modules and panels also provides for high purity of the deposited material, better composition and structure control, uniformity in layer thickness, unlimited combination of different types of thin film layers, and a simpler equipment design.

The present apparatus for making solar cell modules and panels does not need four different PECVD chambers to deposit all the semiconductor layers. The present apparatus for making solar cell modules and panels may repeat some desired deposition steps a number of times as described herein.

In addition, the present apparatus for making solar cell modules and panels provides for high deposition rates over conventional batch type methods of making solar cells. The present apparatus for making solar cell modules and panels is also highly flexible in the types of materials that are deposited on the deposition tube, because of the ease of changing the reagent chemicals that are supplied to the plasma flame. Also, the thicknesses of each layer are easily controlled, thus providing for an easily controllable means of depositing these thin film layers.

In one embodiment, the present apparatus for making solar cell modules and panels includes a means for supporting a substrate, the substrate having an outer surface and an inner surface; plasma torch means located proximal to the inner surface for depositing at least one thin film layer on the inner surface of the substrate, the plasma torch means located a distance from the substrate; and means for supplying reagent chemicals to the plasma torch means, wherein the at least one thin film layer form the silicon thin film solar cell modules.

In another embodiment, the apparatus for making solar cell modules and panels includes a method for making silicon thin film solar cell modules including supporting a substrate, the substrate having an outer surface and an inner surface; providing a high frequency induction coupled plasma torch comprising a coil, the induction coupled plasma torch being selected positionable along the surface area of the inner surface of the substrate; introducing a plasma gas consisting essentially of an inert gas into the high frequency induction coupled plasma torch to form a plasma within the coil; injecting at least one reagent chemicals into the high frequency induction coupled plasma torch; and depositing at least one thin film layer on the inner surface of the substrate, wherein the at least one thin layer comprises the silicon thin film solar cell modules.

### BRIEF DESCRIPTION OF THE DRAWINGS

Illustrative embodiments of the present invention are described in detail below with reference to the attached drawing figures, which are incorporated by reference herein and wherein:

FIG. 1 illustrates a cross-sectional view of a plasma deposition apparatus for making solar cells modules and panels according to an embodiment of the present invention;

FIG. 2 illustrates a cross-sectional view of a plasma deposition apparatus for making solar cell modules and panels according to another embodiment of the present invention;

FIG. 3 illustrates a cross-sectional view of a plasma deposition apparatus for making solar cell modules and panels according to another embodiment of the present invention;

FIG. 4 illustrates an elevation view of a structure stacking of a triple junction photovoltaic cell according to an embodiment of the present invention;

FIG. 5 illustrates a perspective view of a three-dimensional solar panel according to a embodiment of the present invention;

FIG. 6A illustrates a perspective view of a semicircular solar panel according to an embodiment of the present invention;

FIG. 6B illustrates a cross-sectional view of the semicircular solar panel of FIG. 6A according to an embodiment of the present invention;

FIG. 7 illustrates a flow diagram of a process for making solar cells according to an embodiment of the present invention;

FIG. 8 illustrates a flow diagram of another process for making solar cells according to another embodiment of the present invention; and

FIG. 9 illustrates a flow diagram of a process for making solar cell panels according to another embodiment of the present invention.

### DETAILED DESCRIPTION OF THE DRAWINGS

Examples are described, referencing the attached figures and diagrams, that provide persons skilled in the art pertaining to the design and manufacturing of optical fiber with the information required to practice the claimed apparatuses and methods. The use of specific examples is solely to assist in understanding the described and claimed apparatuses and methods. Persons skilled in the art; however, will readily identify further variations, examples, and alternate hardware implementations and arrangements that are within the scope of the appended claims.

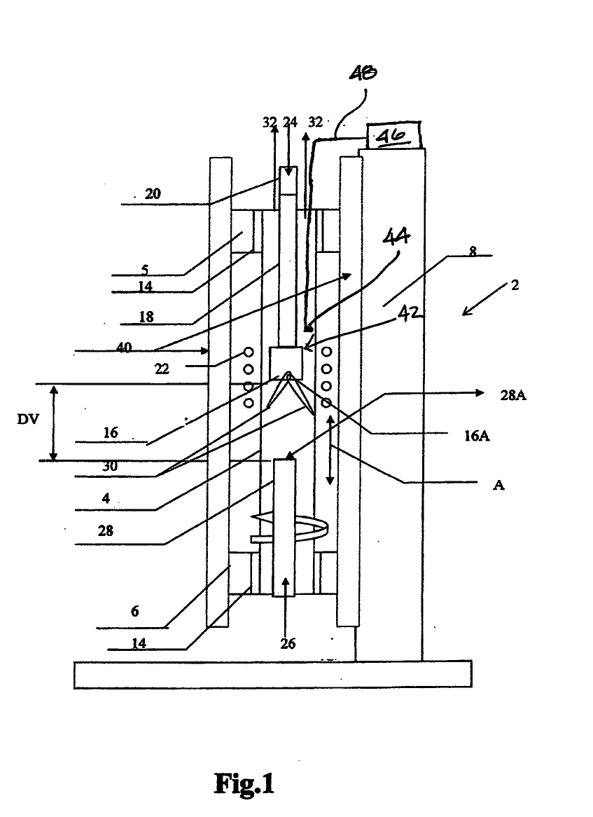

FIG. 1 illustrates an embodiment of a plasma deposition apparatus 2 with a work piece or deposition tube 4 installed, which may be a substrate, supported by a tube or a tube that may become part of a solar cell, solar module, and/or solar panel. The deposition apparatus 2 includes a lathe or chuck support supporting a movable platform 8, the platform 8 being movable in the vertical direction “A” by a platform translation drive (not shown). Mounted on the movable platform 8 is a first rotatable chuck or headstock 5, and a second rotatable chuck or tailstock 6. A pair of spindles 14 for securing the deposition tube 4 and rotating it about the deposition tube's longitudinal axis is included with the headstock 5 and tailstock 6. One or both of the chucks 5 and 6 can be moved in the vertical A direction independently of the other, to permit installation and removal of the deposition tube 4. In one aspect, for operation and safety purposes, the deposition apparatus 2 maybe located inside a deposition chamber (not shown).

A plasma gas feeder nozzle 16 may be supported inside of the deposition tube 4 by a combination support and plasma gas delivery tube 18. The plasma gas feeder nozzle 16 should be substantially centered in the deposition tube 4 and having a rotational gas coupler 20 attached to it. An exemplary tolerance between the plasma gas feeder nozzle 16 and the deposition tube 4 being approximately 1 mm. In one aspect, the materials and construction of the combination support and plasma gas delivery tube 18 must account for the weight of the plasma gas feeder nozzle 16 and the operational temperature conditions. Upon reading the present description, the selection of such construction and materials is a design choice readily made by persons skilled in the art of optical fiber manufacturing. Example materials are quartz and stainless steel. Other example materials include titanium and high-temperature alloys such as, for example, INCONEL of Ni, Cr, Fe and other metals, and equivalents.

An induction coil 22 is supported to surround the outside of the deposition tube 4. A conventional-type radio frequency (“RF”) plasma energy source of, for example, 80 kilowatts (“kW”), is connected to the induction coil 22. It will be understood that the power of the generator may vary in the range from 20 kW to 80 kW, depending on the diameter of the deposition tube 4. For example, for a tube with a 64 mm outer diameter, a typical power range may be between 30 to 40 kW. The induction coil 22 and the plasma gas feeder nozzle 16 are supported to remain preferably stationary in the FIG. 1 depicted alignment. In another embodiment, microwave plasma maybe used as a source of energy to induce the chemical reaction.

A dry plasma gas or plasma forming gas 24, examples including Ar, H₂, He, Kr, or mixtures thereof, preferably with a total moisture content less than 10 ppb OH is delivered from the top end of the deposition tube 4 through the rotational coupler 20, with the combination support and delivery tube 18, into the plasma gas feeder nozzle 16. Reagent chemicals and/or carrier gas (both or individually shown as 26) may be supplied through a tube 28 from the bottom side of the deposition tube 4. In one aspect, when the reagent chemicals are in a gas or vapor phase, it is not necessary to use a carrier gas. To prevent the moisture diffusion from the bottom side of the deposition tube 4, another rotational coupler (not shown) maybe preferably used with the tube 28.

A plasma or plasma flame 30 is produced by the introduction of the plasma gas 24 into the plasma gas feeder nozzle 16 during the energization of the induction coil 22. The plasma gas feeder nozzle 16 and plasma flame 30 may form or be part or all of an induction coupled plasma torch 42. In one example, induction coupled plasma torch 42 may further consist of two quartz tubes: an outer quartz tube (not shown) and a shorter inner quartz tube (not shown), which may be attached to a stainless steel chamber (not shown). In addition, a laser light 44 may be guided, transmitted, and/or reflected to the inside of the tube through optical fiber bundle or mirrors arrangement for scribing lines in the deposited thin film materials as described further herein. The laser 44 may be connected to a power source 46 by power lines 48, as is commonly known in the art.

The tube 28 is preferably held stationary with respect to the combination support and delivery tube 18, so that the distance “DV” between the lower end 16A of the plasma gas feeder nozzle 16 and the upper end 28A of the tube 28 is kept at a fixed distance. An example distance between the lower edge 16A of the plasma gas feeder nozzle 16 and the upper stationary edge of the quartz glass tube 28A may be approximately 200 mm. In one aspect, the distance DV may be a different with different flow rates of plasma gas 24 and reagent chemicals 26.

The reagent chemicals/carrier gas feed 26 from a port are fed from the bottom of the tube 28 and flow against the plasma gas 24. The newly deposited thin film material may be formed on the upper side of the plasma gas feeder nozzle 16. It should be understood that the deposition apparatus 2 may deposit thin film material in both directions when the deposition tube 4 is moving up and also when the tube 28 is moving down relative to the vertical direction A.

An exhaust 32 removes the by-product gases and also these un-deposited soot particles from the upper end of the deposition tube 4. Typically, the pressure inside the deposition tube 4 will be maintained at approximately one atmosphere (“Atm”). The deposition process; however, may be operated in the range from 0.1 to 1.0 Atm. Commercial equipment for implementing the apparatus (not shown) performing the exhaust 32 function is available from various vendors, and is readily selected by one of ordinary skill in the arts pertaining to this description.

In one embodiment, deposition is carried out by repeated cycling of the platform 8 in the vertical direction, with a thin film being deposited with each cycle. An exemplary range of the speed of moving the platform is from approximately 1 meter to 20 meters per minute (“m/min”). The speed may be selected in part based on the layer thickness for each pass. For example, the higher the greater the speed, the thinner the deposited thin film layer will be. In one aspect, two or more pipes 40 with small injection nozzles may be positioned along the length of the pipe that may inject temperature controlled liquid or gas onto the outside wall of the deposition tube 4. This may maintain the desired deposition temperature of the deposition tube 4.

As shown in FIG. 1, the carrier gas 26 and reagent chemicals 26 feed from tube 28 and they flow against the plasma gas 24 from the combination support and plasma gas delivery tube 18, thus newly deposited thin film material will be formed on the upper side of the plasma gas feeder nozzle 16. It should be understood that the deposition apparatus 2 may deposit thin film material both when the tube 4 is moving up and when the deposition tube 4 is moving down, relative to the vertical direction A. It is possible to supply the reagent chemicals 26 without the tube 28, but use of the tube 28 is typically preferable, as it would generally enable more stable and better-controlled conditions for the chemical reaction. In addition, the plasma gas 24 may be supplied from the top and the reagent chemicals 26 may be supplied from the bottom of the deposition apparatus 2. Also, the plasma gas 24 may be supplied from the bottom and the reagent chemicals 26 may be supplied from the top of the deposition apparatus 2, especially when the reagent chemicals 26 may be in the form of solids.

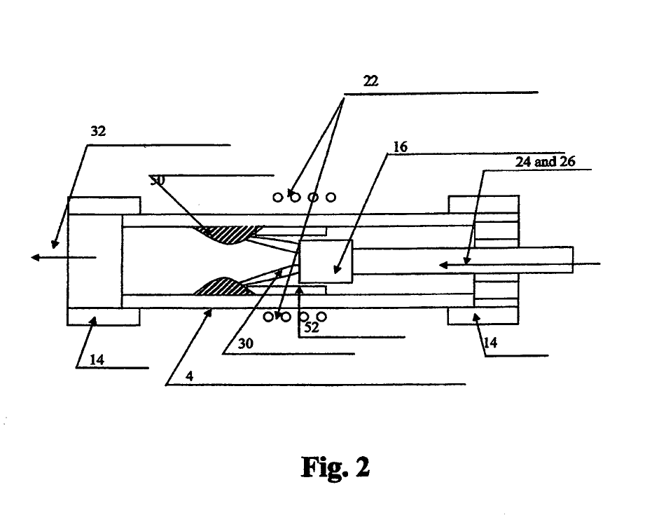

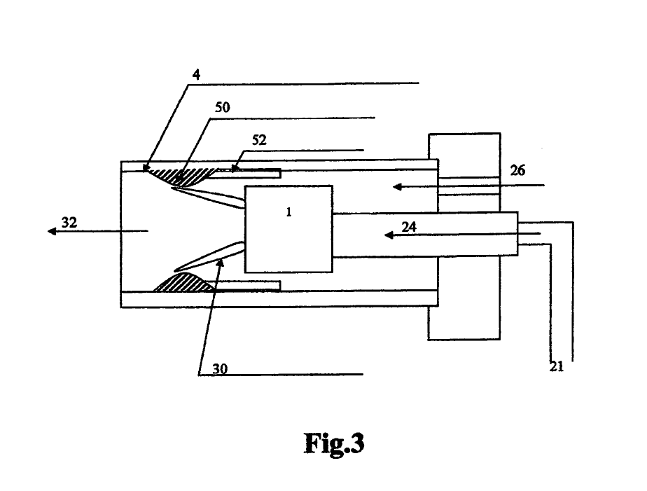

In one embodiment, the introduction of reagent chemicals 26 and plasma gas 24 may be introduced into the deposition tube 4 at the same end of the deposition tube 4. FIG. 2 illustrates an embodiment of a deposition apparatus 2 oriented in a horizontal position. In this embodiment, the reagent chemicals 26 and plasma gas 24 are supplied into the deposition tube 4 from the same end of the deposition tube 4. FIG. 3 illustrates an embodiment of a deposition apparatus 2 also oriented in a horizontal position. In this embodiment, the plasma gas 24 may be supplied through the center of the deposition tube 4 while the reagent chemicals 26 is supplied to the deposition apparatus 2 nearer to the inner wall of the deposition tube 4.

In one aspect, a certain length of deposition tube 4 may produce a corresponding area of a solar panel. For example, a deposition tube 4 having a length of approximately 150 cm and a diameter of approximately 30 cm may produce a substrate panel having an area of approximately 94 cm by 150 cm. In addition, it is also possible to have a deposition tube 4 with greater or lesser lengths and diameters to produce solar cells, substrates, modules, and/or panels having desired areas, for example.

The plasma forming gas or plasma gas 24 may be a gas that has a low activation energy and that may have a chemically inert character such that no oxide or nitride will be formed. Some exemplary gases include argon and hydrogen. Mixtures of the plasma forming gas or plasma gas 24 may also be used with the deposition apparatus 2. For example, argon mixed with hydrogen may be used preferably when a reducing environment is preferred.

The reagent chemicals 26 may be chemical elements or compounds that contain elements or elements required for making solar cells, modules, panels, and the like. The reagent chemicals 26 may be in a desirable form, such as gas, vapor, aerosol, and/or small particles. Alternatively, a powder (such as nanoparticle powder) of the semiconductor material such as pure silicon can be introduced to the plasma gas feeder nozzle 16 and/or induction coupled plasma torch 42 at the appropriate position in an inert atmosphere, such as argon in atmospheric or under vacuum conditions.

The reaction product that produces the thin film material is produced by the reaction of the reagent chemicals 26 in the presence of the plasma gas feeder nozzle 16 and/or induction coupled plasma torch 42. The induction coupled plasma torch 42 preferably uses an inert plasma gas to form the plasma where the reaction takes place between the reagent chemicals 26 and the induction coupled plasma torch 42 for depositing the thin film material or reaction product on the inside of the deposition tube 4. Some exemplary reagent chemicals 26 include silane, hydrogen, methane, diborane, trimethylborone, phosphine, and mixtures thereof. The reagent chemicals 26 may include or be additional forms of matter such as gases, vapors, aerosols, small particles, or powders.

The thin film material of reaction product is preferably a single element, compound, or mixture of elements or compounds and includes elements and compounds as copper, indium, gallium, selenium, silicon, intrinsic I-type layers, p-type doped silicon layers, and N-type doped silicon. In one embodiment, the thin film material is a copper indium gallium diselenide (“CIGS”) layer that is found in solar cells.

The typical solar cell may have P-I-N or N-I-P layer structures. Further, an individual layer for the silicon solar cell can be formed with the following chemicals. For intrinsic silicon (I-type layer), silane (“SiH₄”), trichlorosilane (“TCS” SiHCL₃), and/or silicon tetrachloride (“STC; SiCl₄) may be materials used for these silicon layers. In addition, hydrogen (“H₂”) gas may be also added to the gas stream for making the desired Si: H I-type layer. For P-type doped silicon, either a SiH₄, H₂, and/or B₂H₆ gas mixture or a SiH₄, H₂, and Trimethylboron B(CH₃)₃ gas mixture may be used, for example. For N-type doped silicon, either a SiH₄ and PH₃ gas mixture or a SiH₄, H₂, and PH₃ gas mixture may be used, for example. When depositing layers containing germanium, germanium hydride (GeH₄) may be preferably used as the reagent chemicals 26. In addition, germanium tetrachloride (GeCl₄) or germanium tetrafluoride (GeF₄) may preferably be used as the reagent chemicals 26.

Further, carbon maybe added to a silicon-germanium alloy to relieve the strain between the layers of silicon-germanium and silicon, and it may also change the band gap of the alloy. The carbon may be added to the silicon-germanium mixture to allow for the formation of the ternary silicon-germanium-carbon, where one carbon atom compensates the strain of approximately ten germanium atoms. This alloy may allow the growth of layers with increased thickness and germanium concentration while reducing the number of defects. Some exemplary carbon containing compounds include CH₃SiH₃ and/or CH₄. As discussed herein, the present apparatus for making solar cell modules and panels does not require adding extra chambers or additional equipment to make the ternary alloy, it only requires the addition of these chemical compounds be supplied to the plasma flame 30 with the reagent chemicals 26 feed.

The deposition tube 4 may be quartz glass tubing, a high temperature polyimide film supported by glass tubing or any tubes made of non-metallic materials that are suitable for solar cell applications.

In one aspect, the reagent chemicals 26 used may be purchased from a commercial supplier. Further, commercial chemical delivery systems may be obtained for delivering a desired element, compound, or mixture of compounds to the deposition apparatus 2. For example, the company, Applied Materials or iCon Dynamics, may be a source for turnkey systems. Additionally, it is also possible to build custom systems with individual control components. For the gas phase reagent chemicals 26, the deposition apparatus 2 may use a mass flow controller to regulate the gaseous reagent chemicals 26. For reagent chemicals 26 in a liquid phase, the deposition apparatus 2 may use a carrier gas to transport the vapor phase of the reagent chemicals 26 or a flash evaporator for preparing the reagent chemicals 26 prior to injecting into the induction coupled plasma torch 42.

Generally, a larger area photovoltaic cell will collect more solar energy and be better able to convert more optical energy into electrical power than a smaller area photovoltaic cell. Nevertheless, in order to better utilize the generated energy, it is preferable to break the large cells into small ones and make proper interconnections between the individual solar cells to form a module or panel that will have the desired output characteristics, such as open circuit voltage (“V_{OC}”), short circuit current (“I_{SC}”), and fill factor (“FF”), which is defined as the maximum power produced at the maximum power point, divided by the product of I_{SC} and V_{OC}. To convert the solar cells into a solar module, the apparatus may include a laser scribing sequence that enables the front and back of adjacent solar cells to be directly interconnected in series with no need for further solder connections between the cells. There exist two common methods for forming these interconnections on a solar module.

One method uses a scribing process with a laser 44 that scribes after each individual layer is deposited or formed, while the other method scribes after all of the layers have been deposited or formed. The later method involves scribing all the layers after they have been deposited and is a method that can be used after the completed deposited deposition tube 4 is removed from the deposition drum. The deposition tube 4 may be mounted on a laser scribing system, as known commonly in the art. Some exemplary systems are manufactured by U.S. Laser Corp. and the Synova/Manz Automation entity.

The former method includes scribing after each layer of thin film is deposited. This method may not require the deposition tube 4 to be removed from the deposition apparatus 2, but just that the scribing process is performed after each thin film layer is deposited. Preferably, a laser system with an optical fiber bundle and focusing optics to deliver the high power laser energy may be used. The end of the fiber bundle may be mounted on the inside of the tubing close to the plasma gas feeder nozzle 16 and aimed toward the inner wall of the deposition tube 4 where the deposited thin film is located. The laser 44 and its power supply 46 may be positioned outside the deposition chamber or deposition apparatus 2. When the rotating motion of the deposition tube 4 stops, then transverse motion of the headstock 5 and tailstock 6 can scribe the line parallel to the longitudinal axis of the deposition tube 4. When the transverse motion stops, then the rotating motion of the deposition tube 4 will scribe the lines perpendicular to the longitudinal axis of the deposition tube 4. With proper index for each line, the designed module pattern may be easily formed. One exemplary laser system is manufactured by Newport Corporation or Coherent Corporation. Additionally, a fiber laser system for scribing the interconnected grids and cells may be used to form the solar cell module.

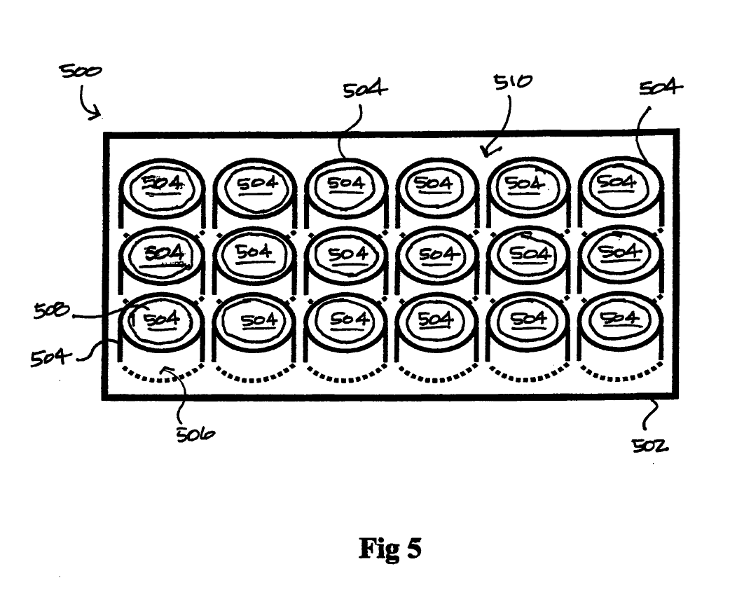

A typical solar panel is flat and is generally rectangular-shaped in two dimensions. The present apparatus for making solar cell modules and panels also includes three-dimensional solar panels without having extra steps to form them. For example, once all of the thin film layers have been deposited on the deposition tube 4, the deposition tube 4 may be cut laterally or perpendicularly through the longitudinal axis of the deposition tube 4 to produce three-dimensional solar modules. Further, these three-dimensional solar modules may be mounted on a typical flat rectangular panel to produce sections along the solar panel as shown in FIG. 5, which illustrates an illustrative embodiment 500 of a circular three-dimensional solar panel of the present invention. The solar panel 500 may include a panel substrate 502 upon which a plurality 510 of solar cells 504. The solar cells 504 are produced by cutting a deposition tube 4 perpendicularly at a length shown as 506. The deposition tube 4 is cut into these solar cells 504 after all of the thin film layers have been deposited on the deposition tube 4. These solar cells 504 may be interconnected electrically by having connectors or wires integrated into the panel substrate 502, or by other means. As shown, the solar energy absorbing area of the solar panel 500 is greater than other conventional rectangular flat solar cell panels.

As the sun moves over the solar panel 500, the solar cells 504 do not need to be tilted or the panel otherwise moved to follow the sun. This is because the sun light strikes the absorbing layer on the inner wall or surface 508 of the solar cells 504 converting the light into electrical energy. Light rays reflecting off of the inner walls 508 of the solar cells 504 may be absorbed on other portions of the inner walls 508 of the solar cells 504, which is then converted into electrical energy. The solar panels 500 produced by the present apparatus for making solar cell modules and panels increases the absorbing area of the solar panels 500 and effectively traps and absorbs reflecting light rays and solar energy.

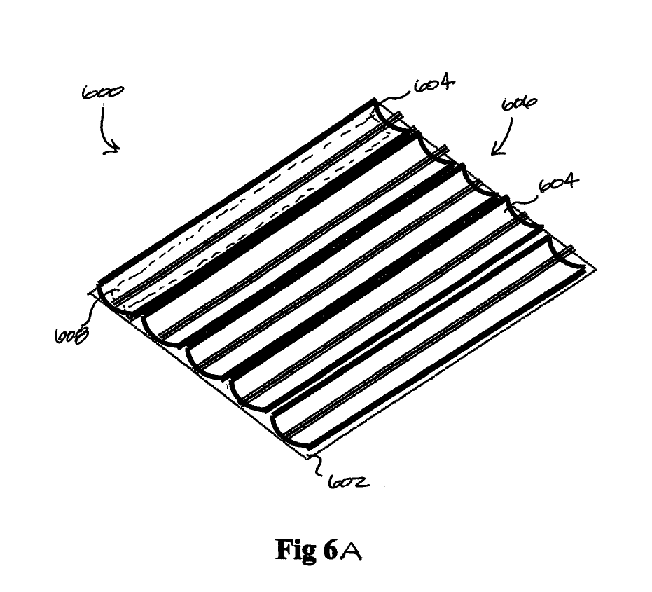

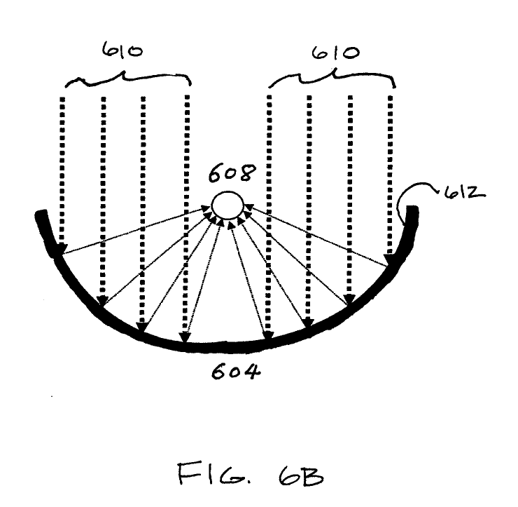

FIG. 6A is an illustrative embodiment 600 of a semicircular solar panel of the present invention. The present apparatus for making solar cell modules and panels may also produce solar panels that have a semicircular panel design. In this embodiment, the solar panel 600 is produced by cutting the deposition tube 4 along the longitudinal or center axis and mounting the semicircular solar cells 604 side-by-side onto a panel substrate 602. Due to the shape of the semicircular deposition tubes 604 having more available surface area than a conventional flat solar panel, the solar panel 600 absorbs more light than a conventional flat solar panel. In addition, all of the light that is reflected off of the surface of a conventional flat solar panel is lost. Conversely, the shape of the solar cells 604 of the solar panel 600 reflects the light towards the center of its semicircular shape. This reflected light may be captured by a solar cell 608 at the focal point (center of the circle) of each of the solar cells 604. Only one solar cell 608 is shown, but any number of the solar cells 604 may included a solar cell 608 located at the focal point of the semicircle. In addition, rather than having a solar cell 608 located at the focal point of the solar cells 604, a heat pipe or other conduit containing a fluid for absorbing the heat of the reflected light may be used.

FIG. 6B is an illustrative embodiment of a semicircular deposition tube 604 in proximity to a solar cell 608 showing sun light ray traces 610 from the sun that are reflected off of the inner surface 612 of the semicircular deposition tubes 604. In this embodiment, the sun is far away from the semicircular deposition tubes 604 and solar cell 608, thus the incident light ray traces 610 may be substantially parallel when they contact the inner surface 612 of the semicircular deposition tubes 604. The solar energy (sun light) will emit light that contacts the inner surface 612 of the semicircular deposition tubes 604 that may be reflected back towards the solar cell 608. In this embodiment, part of the solar energy is absorbed by the semicircular deposition tubes 604 of the solar panel 600 and part of the solar energy will be absorbed by the solar cell 608. Due to the shape of the semicircular deposition tubes 604, the reflected light is directed towards or focused on the solar cell 608. As discussed herein, the solar cell 608 is preferably positioned and/or located such that it is at the focal point of the reflected light ray traces 610 from the sun. In one aspect, the solar cell 608 may be a heat absorption pipe that contains a fluid for absorbing the heat from the reflected light.

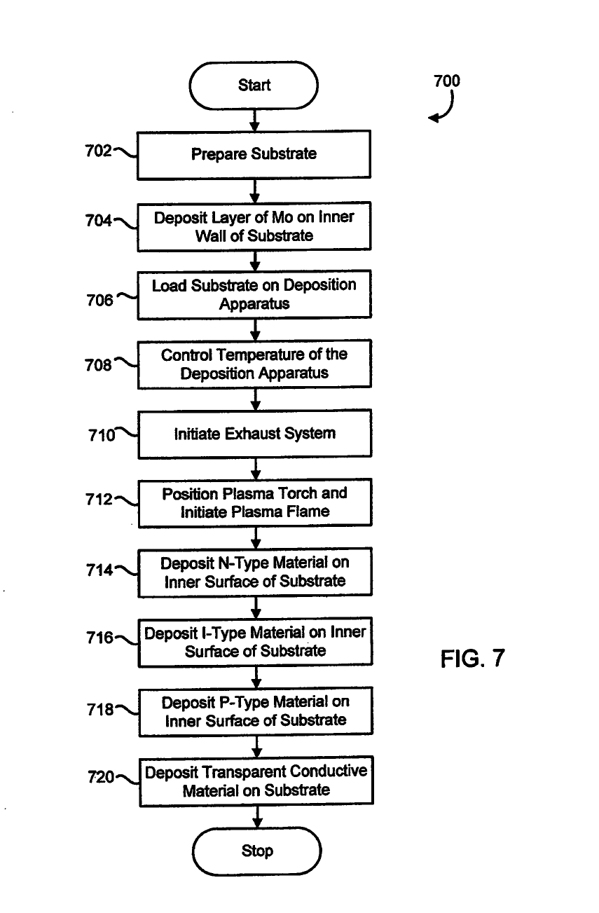

In addition to the aforementioned aspects and embodiments of the present deposition apparatus 2, the present invention further includes methods for making solar cell modules and panels. FIG. 7 illustrates a flow diagram of an embodiment 700 of one such process. In this embodiment, a N-I-P type film silicon photovoltaic cell on a glass substrate is made. In step 702, the surfaces of a glass tubing substrate are washed, cleaned, and preferably dried. In one aspect, other materials may be used for the deposition tube 4, such as high temperature polymer films. In step 704, a thin layer of molybdenum is deposited by the deposition apparatus 2 onto the inner surface or inner wall of the deposition tube 4. This step may be either performed by the deposition apparatus 2 or by a separate instrument, machine, or deposition apparatus for making solar cell modules and panels. A non-metallic tubing may be used as a support for the deposition tube 4 and the thin film may be mounted on the inner surface or wall of the deposition tube 4.

In step 706, the substrate or deposition tube 4 is loaded on the deposition apparatus 2. This step may further include connecting the plasma gas 24 and reagent chemicals 26 to the plasma gas feeder nozzle 16 and rotational gas coupler 20. In step 708, the temperature of the deposition apparatus 2 and/or deposition tube 4 are temperature controlled by a heating/cooling unit (not shown). An exemplary temperature is approximately 350° C., for example. Other temperatures may be used in accordance with one skilled in the art. In one aspect, the pressure may be substantially atmospheric pressure and the temperature range maybe from about 150° C. to about 350° C.

In step 710, the exhaust system is operated. In one aspect, the main function of the exhaust system is to remove the by-product gases and un-deposited reactant products. It also needs to be balanced such that the pressure is preferably maintained to be close to atmospheric pressure. In step 712, the induction coupled plasma torch 42 may be located or positioned in an initial position relative to the deposition tube 4. In one aspect, the induction coupled plasma torch 42 may be positioned at one end or the other of the deposition tube 4. This step may further include rotating the deposition tube 4 relative to the induction coupled plasma torch 42. In another aspect, the induction coupled plasma torch 42 may be rotated relative to the deposition tube 4. This step may further include igniting the plasma flame 30 of the induction coupled plasma torch 42. This step may further include stabilizing the plasma flame 30 and injecting the reagent chemicals 26 into the plasma flame 30. Further, the induction coupled plasma torch 42 may then be moved or traversed relative to the deposition tube 4 so that a thin layer of the reaction product from the reagent chemicals 26 in the presence of the plasma flame 30. This step may further include traversing the headstock 5 and tailstock 6 relative to the deposition apparatus 2 so that the thin film material is deposited along the inner surface of the deposition tube 4.

In step 714, a layer of thin film first material is deposited on the inner surface of the deposition tube 4. In one embodiment, the first layer of thin film material may be a N-type doped silicon where the reagent chemicals 26 may be SiCl₄, H₂, and PH₃. The headstock 5 and tailstock 6 may move up and down or traverse the deposition tube 4 such that a desired thickness of the thin layer material is deposited on the inner surface of the deposition tube 4. This process may further be controlled by controlling the flow rates of the reagent chemicals 26, in addition to the speed of the rotation and the traverse speed of the headstock 5 and tailstock 6. The SiCl₄ may be used as a source reagent for the silicon. In addition, the source for the silicon may also be SiHCl₃, SiH₄, and/or SiF₄, for example. Mixtures of the compounds may also be used as the source of the silicon. In one aspect, the thickness of the first layer of thin film material is preferably between 0.1 μm to about 0.5 μm, for example.

In step 716, a thin film layer of a second material is deposited on the inner surface of the deposition tube 4. In one embodiment, the second layer of thin film material may be an I-Type silicon by ceasing the flow of the PH₃ and increasing the supply of H₂ to the plasma flame 30. The headstock 5 and tailstock 6 may traverse the deposition tube 4 back and forth until a desired thickness of the I-Type silicon is deposited on the deposition tube 4. In one aspect, the thickness of the second layer of thin film material is preferably between 1 μm and 5 μm, for example. More preferably, the thickness maybe between 1 μm and 2 μm.

In step 718, a thin film layer of a third material may be deposited on the inner surface of the deposition tube 4. In one embodiment, the third layer of thin film material may be a P-Type doped silicon material. The supply of H₂ to the plasma flame 30 may be decreased or reduced and the B₂H₆ may be added to the mixture of reagent chemicals 26. The headstock 5 and tailstock 6 may continue to traverse the deposition tube 4 until a desired thickness of the P-Type material is deposited. In one aspect, the thickness of the third layer of thin film material is preferably between 0.3 μm and 0.8 μm, for example.

At the end of the deposition steps, the reagent chemicals 26 may be stopped and the plasma flame 30 may be turned off. Also, the rotating and transversing functions may be stopped as well. Then the deposition tube 4 may be removed from the deposition apparatus 2. In step 720, a layer of transparent conductive metal oxide (“TCO”) may be deposited on the deposition tube 4 as a top electrode. This step may include depositing the TCO in a vacuum evaporation process chamber as is commonly known to those skilled in the art. The TCO material may be a single or mixture of oxides, including oxide of indium, tin, or zinc. This process produces a photovoltaic cell, which may then be further processed photovoltaic module or panel as further described herein and be assembled into a photovoltaic system.

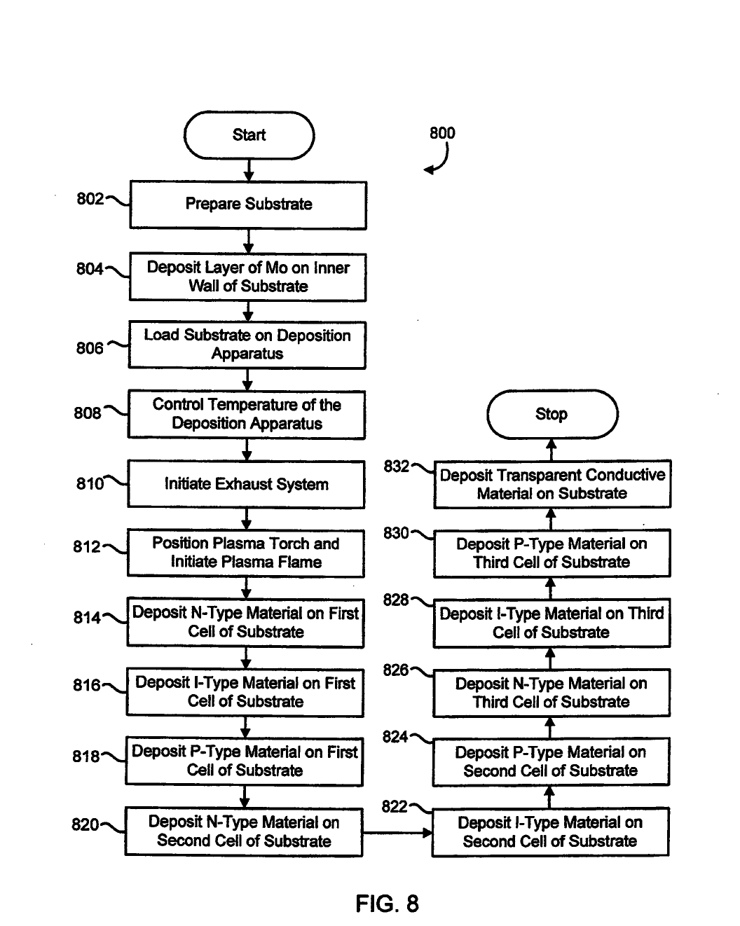

FIG. 8 illustrates a flow diagram of an embodiment 800 a process for making a multiple-junction photovoltaic solar cell. In step 802, the surfaces of a substrate, such as glass tubing, are washed, cleaned, and preferably dried. In one aspect, other materials may be used for the deposition tube 4, such as high temperature polymer films. A non-metallic tubing may be used as a support for the deposition tube 4 and the thin film may be mounted on the inner surface or wall of the deposition tube 4. In step 804, a thin layer of molybdenum is deposited by the deposition apparatus 2 onto the inner surface or inner wall of the deposition tube 4. This step may be either performed by the deposition apparatus 2 or by a separate instrument, machine, or deposition apparatus for making solar cell modules and panels.

In step 806, the substrate or deposition tube 4 is loaded on the deposition apparatus 2. This step may further include connecting the plasma gas 24 and reagent chemicals 26 to the plasma gas feeder nozzle 16 and rotational gas coupler 20. In step 808, the temperature of the deposition apparatus 2 and/or deposition tube 4 are temperature controlled by a heating/cooling unit (not shown). An exemplary temperature is approximately 350° C., for example. Other temperatures may be used in accordance with one skilled in the art. In one aspect, the pressure may be substantially atmospheric pressure and the temperature range may be from about 150° C. to about 400° C. More preferably, the temperature maybe from about 150° C. to about 350° C.

In step 810, the exhaust system is operated. In step 812, the induction coupled plasma torch 42 may be located or positioned in an initial position relative to the deposition tube 4. In one aspect, the main function of the exhaust system is to remove the by-product gases and un-deposited reactant products. It also needs to be balanced such that the pressure is preferably maintained to be close to atmospheric pressure. In one aspect, the induction coupled plasma torch 42 may be positioned at one end or the other of the deposition tube 4. This step may further include rotating the deposition tube 4 relative to the induction coupled plasma torch 42. In another aspect, the induction coupled plasma torch 42 may be rotated relative to the deposition tube 4. This step may further include igniting the plasma flame 30 of the induction coupled plasma torch 42. This step may further include stabilizing the plasma flame 30 and injecting the reagent chemicals 26 into the plasma flame 30. Further, the induction coupled plasma torch 42 may then be moved or traversed relative to the deposition tube 4 so that a thin layer of the reaction product from the reagent chemicals 26 in the presence of the plasma flame 30. This step may further include traversing the headstock 5 and tailstock 6 relative to the deposition apparatus 2 so that the thin film material is deposited along the inner surface of the deposition tube 4.

In step 814, a layer of thin film first material is deposited on the inner surface of the deposition tube 4. In one embodiment, the first layer of thin film material may be a N-type doped silicon where the reagent chemicals 26 may be SiCl₄, H₂, and PH₃. The headstock 5 and tailstock 6 may move up and down or traverse the deposition tube 4 such that a desired thickness of the thin layer material is deposited on the inner surface of the deposition tube 4. This process may further be controlled by controlling the flow rates of the reagent chemicals 26, in addition to the speed of the rotation and the traverse speed of the headstock 5 and tailstock 6. The SiCl₄ may be used as a source reagent for the silicon. In addition, the source for the silicon may also be SiHCl₃, SiH₄, and/or SiF₄, for example. Mixtures of the compounds may also be used as the source of the silicon. In one aspect, the thickness of the first layer of thin film material is preferably between 0.2 μm and 0.5 μm, for example.

In step 816, a thin film layer of a second material is deposited on the inner surface of the deposition tube 4. In one embodiment, the second layer of thin film material may be an I-Type silicon-germanium material produced by increasing the supply of H₂ to the plasma flame 30. Preferably, the concentration of germanium is higher than the concentration of silicon. In another aspect, other germanium containing compounds may be used. For example, a layer having a bandgap of approximately 1.4 ev, the percentage of germanium in the silicon germanium (SiGe) may be from about 40% to about 50%. The supply of PH₃ may be turned off for during the deposition of this layer. In addition, the concentrations of GeH₄ and H₂ may be introduced into the plasma flame 30. The headstock 5 and tailstock 6 may traverse the deposition tube 4 back and forth until a desired thickness of the I-Type silicon is deposited on the deposition tube 4. In one aspect, the thickness of the second layer of thin film material is preferably between 1.5 μm and 5 μm, for example.

In step 818, a thin film layer of a third material may be deposited on the inner surface of the deposition tube 4. In one embodiment, the third layer of thin film material may be a P-Type doped silicon material. The supply of H₂ to the plasma flame 30 may be decreased or reduced and the supply of GeH₄ will be turned off and B₂H₆ may be added to the mixture of reagent chemicals 26. The headstock 5 and tailstock 6 may continue to traverse the deposition tube 4 until a desired thickness of the P-Type material is deposited. In one aspect, the thickness of the third layer of thin film material is preferably between 0.2 μm and 0.8 μm, for example. The steps 814-818 produce a first solar in the multiple-junction photovoltaic solar cell.

In step 820, a first layer of a second solar cell is produced on the deposition tube 4. In this step, a layer of thin film first material is deposited for a second solar cell on the inner surface of the deposition tube 4. In one embodiment, the first layer of thin film material may be a N-type doped silicon where the reagent chemicals 26 may be SiCl₄, H₂, and PH₃. In addition, the previous supply of B₂H₆ will be turned off and a supply of PH₃ will be supplied to the plasma flame 30. The headstock 5 and tailstock 6 may move up and down or traverse the deposition tube 4 such that a desired thickness of the thin layer material is deposited on the inner surface of the deposition tube 4. This process may further be controlled by controlling the flow rates of the reagent chemicals 26, in addition to the speed of the rotation and the traverse speed of the headstock 5 and tailstock 6. In one aspect, the thickness of the thin film layer material is preferably between 0.2 μm and 0.5 μm, for example.

In step 822, a thin film layer of a second material for the second solar cell is deposited on the inner surface of the deposition tube 4. In one embodiment, the second layer of thin film material may be an I-Type silicon-germanium produced by adding a supply of GeH₄, but less than that added in step 816 above. Preferably, the concentration of germanium is lower than the concentration of silicon. The supply of PH₃ may be turned off for during the deposition of this layer. In addition, the concentrations of GeH₄ and H₂ may be introduced into the plasma flame 30. The headstock 5 and tailstock 6 may traverse the deposition tube 4 back and forth until a desired thickness of the I-Type silicon is deposited on the deposition tube 4. In one aspect, the thickness of the second layer of thin film material is preferably between 1 mm and 3 mm, for example. More preferably, the thickness of the second layer of thin film material is between 1 mm and 1.5 mm. In one aspect, the concentration of germanium in the silicon germanium (SiGe) is from about 10% to about 20%. Additionally, the concentration of hydrogen may effect the bandgap of this layer. In another aspect, higher concentrations of hydrogen may require more germanium in the SiGe compound to achieve the desired 1.6 ev bandgap.

In step 824, a thin film layer of a third material for the second solar cell may be deposited on the inner surface of the deposition tube 4. In one embodiment, the third layer of thin film material maybe a P-Type doped silicon material. The supply of H₂ to the plasma flame 30 maybe decreased or reduced and the supply of GeH₄ will be turned off and B₂H₆ may be added to the mixture of reagent chemicals 26 supplied to the plasma flame 30. The headstock 5 and tailstock 6 may continue to traverse the deposition tube 4 until a desired thickness of the P-Type material is deposited. In one aspect, the thickness of the third layer of thin film material is preferably between 0.2 μm and 0.8 μm, for example. The steps 820-824 produce a second solar cell in the multiple-junction photovoltaic solar cell.

In step 826, a first layer of a third solar cell is produced on the deposition tube 4. In this step, a layer of thin film first material is deposited for a third solar cell on the inner surface of the deposition tube 4. In one embodiment, the first layer of thin film material may be a N-type doped silicon where the reagent chemicals 26 may be SiCl₄, H₂, and PH₃. In addition, the previous supply of B₂H₆ may be turned off and a supply of PH₃ may be supplied to the plasma flame 30. The headstock 5 and tailstock 6 may move up and down or traverse the deposition tube 4 such that a desired thickness of the thin layer material is deposited on the inner surface of the deposition tube 4. This process may further be controlled by controlling the flow rates of the reagent chemicals 26, in addition to the speed of the rotation and the traverse speed of the headstock 5 and tailstock 6. In one aspect, the thickness of this thin film material is preferably between 0.2 μm and 0.5 μm, for example.

In step 828, a thin film layer of a second material for the third solar cell is deposited on the inner surface of the deposition tube 4. In one embodiment, the second layer of thin film material may be an I-Type silicon material produced by ceasing the flow of the PH₃ and increasing the supply of H₂ to the plasma flame 30. The headstock 5 and tailstock 6 may traverse the deposition tube 4 back and forth until a desired thickness of the I-Type silicon is deposited on the deposition tube 4. In one aspect, the thickness of this layer of thin film material is preferably between 0.8 μm and 1.0 μm, for example, but it may be as thick as approximately 2 μm.

In step 830, a thin film layer of a third material for the third solar cell may be deposited on the inner surface of the deposition tube 4. In one embodiment, the third layer of thin film material may be a P-Type doped silicon material. The supply of H₂ to the plasma flame 30 may be decreased or reduced and a supply of B₂H₆ may be added to the mixture of reagent chemicals 26 supplied to the plasma flame 30. The headstock 5 and tailstock 6 may continue to traverse the deposition tube 4 until a desired thickness of the P-Type material is deposited. In one aspect, the thickness of this layer of thin film material is preferably between 0.2 μm and 0.5 μm, for example. The steps 826-830 produce a third solar cell in the multiple-junction photovoltaic solar cell. Collectively, steps 802-830 produce a formed triple-junction photovoltaic solar cell. At the end of the deposition steps, the reagent chemicals 26 may be stopped and the plasma flame 30 may be turned off. Also, the rotating and transversing functions may be stopped as well. Then the deposition tube 4 may be removed from the deposition apparatus 2.

In step 832, a layer of transparent conductive metal oxide (“TCO”) may be deposited on the deposition tube 4 as a top electrode. This step may include depositing the TCO in a vacuum evaporation process chamber as is commonly known to those skilled in the art. The TCO material maybe a single or mixture of oxides, including oxide of indium, tin, or zinc. This process produces a triple-junction photovoltaic solar cell, which may then be further processed photovoltaic module or panel as further described herein and be assembled into a photovoltaic system.

The present apparatus for making solar cell modules and panels does not require the need to move the target or substrate from one chamber to another chamber, back and forth, to deposit layers of different composition. The present apparatus for making solar cell modules and panels preferably just changes the supply of different chemicals to the plasma flame 30 as described herein. This not only reduces the processing time, but also has the advantage to allow users to build multiple junction cells when it is desirable, without adding more chambers. Further, the present apparatus for making solar cell modules and panels deposits thin films with a capability of producing different sizes; the present apparatus for making solar cell modules and panels allows for easily changing the length and/or diameter of the deposition tube 4 used in the deposition process. For example, the present apparatus for making solar cell modules and panels may be used to deposit these thin film layers on a deposition tube 4 having a size of approximately 94 cm×150 cm, which is approximately two order of magnitude larger than the area reported in the prior art.

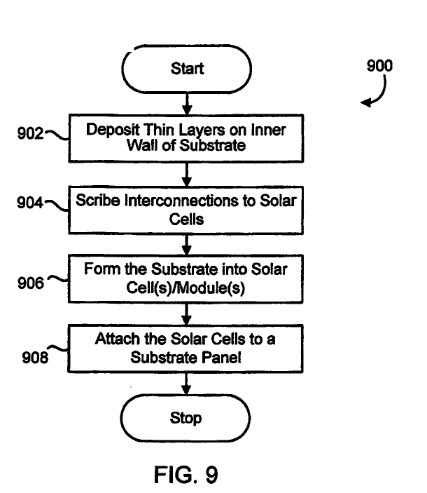

FIG. 9 illustrates a flow diagram of an embodiment 900 a process for making a solar panel. In step 902, thin film layers are deposited on a deposition tube 4 as described herein. In step 904, the solar cell interconnections are scribed in the deposition tube 4 as described herein. In step 906, the solar cell module is formed or cut into portions as described herein. In step 908, the solar cell modules are then affixed or attached to a panel substrate.

A single crystal silicon may have a energy band gap (Eg) of about 1.1 electron volt (ev). When making silicon thin film photovoltaic cell, because of the addition of hydrogen to the silicon as the absorbing layer, the band gap becomes about 1.8 ev and it is away from the peak of the solar spectrum (1.5 ev). In order to better utilize the solar energy absorption at peak band, the band gap may need to be lowered or increase the wavelength of the absorbing layer of the solar cell.

In one embodiment, the present apparatus for making solar cell modules and panels includes using different materials that may have similar crystal structure with different band gaps. For example, silicon and germanium have similar crystal structures, but with different band gaps. In addition, as the mixing ratio of the silicon and germanium may be changed, which may also change the band gap. When using the mixture of both as an absorbing layer on a photovoltaic cell, they can be configured to absorb the photon energy from a different wavelength region of the solar spectra. The present apparatus for making solar cell modules and panels includes making a solar cell with multiple tandem thin film layers of silicon and silicon-germanium alloy, the solar cell may allow more solar energy to be absorbed, thus it will improve the efficiency of the photovoltaic cell. Because of the similarity in the crystal structure of the silicon and germanium, there will be fewer concerns with the mismatch between the layers.

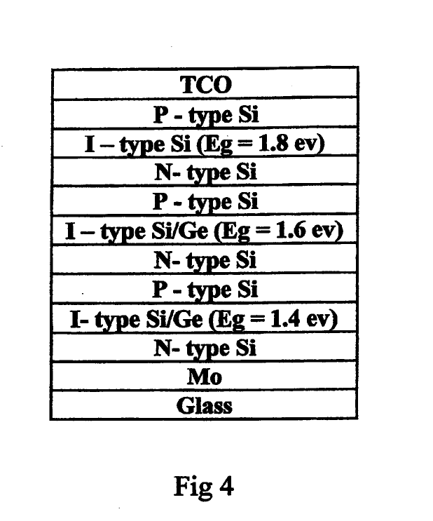

Further, because of the similarity of the physical properties of silicon and germanium, it is possible to make a multiple-junction solar cell to cover wider solar spectrum ranges and improve the cell efficiency. For example, FIG. 4 illustrates a stacking relationship of the different layers for a multiple-junction photovoltaic solar cell according to an embodiment of the present apparatus for making solar cell modules and panels. Relating to the embodiments described above, some light from the sun may pass through the energy absorbing layers of the solar cells, while other light is absorbed in the energy absorbing layers of the solar cells. In one aspect, to match the same amount of energy being absorbed, the layer thicknesses may become thicker for the first or bottom absorbing layers.

Although there has been described what is at present considered to be the preferred embodiments of the apparatus for making solar cell modules and panels, it will be understood that the present apparatus for making solar cell modules and panels can be embodied in other specific forms without departing from the spirit or essential characteristics thereof. For example, additional plasma torches or different combinations of deposition modules, other than those described herein could be used without departing from the spirit or essential characteristics of the present apparatus for making solar cell modules and panels. The present embodiments are, therefore, to be considered in all aspects as illustrative and not restrictive. The scope of the invention is indicated by the appended claims rather than the foregoing description.

What is claimed:

1. A plasma inside vapor deposition apparatus for making silicon thin film solar cell modules comprising:
means for supporting a substrate, said substrate having an outer surface and an inner surface;
plasma torch means located proximal to said inner surface for depositing at least one thin film layer on said inner surface of said substrate, said plasma torch means located a distance from said substrate; and
means for supplying reagent chemicals to said plasma torch means, wherein said at least one thin film layer form said silicon thin film solar cell modules.

2. The plasma inside vapor deposition apparatus for making silicon thin film solar cell modules of claim 1, wherein said means for supporting comprises:
a movable platform for moving said substrate along its longitudinal axis relative to said plasma torch means.

3. The plasma inside vapor deposition apparatus for making silicon thin film solar cell modules of claim 1, wherein said means for supporting further comprises:
at least one rotatable chuck for rotating said substrate about its longitudinal axis relative to said plasma torch means.

4. The plasma inside vapor deposition apparatus for making silicon thin film solar cell modules of claim 1, further comprising:
a scribe located proximal to said inner surface for scribing interconnections in said at least one thin film layer to produce said silicon thin film solar cell modules.

5. The plasma inside vapor deposition apparatus for making silicon thin film solar cell modules of claim 4, wherein said scribe is a laser.

6. The plasma inside vapor deposition apparatus for making silicon thin film solar cell modules of claim 4, further comprising:
at least one injection nozzle located proximal to said outer surface for injecting one of a liquid and gas to control the temperature of the substrate.

7. The plasma inside vapor deposition apparatus for making silicon thin film solar cell modules of claim 4, wherein said apparatus is oriented in a substantially vertical position.

8. The plasma inside vapor deposition apparatus for making silicon thin film solar cell modules of claim 4, wherein said apparatus is oriented in a substantially horizontal position.

9. The plasma inside vapor deposition apparatus for making silicon thin film solar cell modules of claim 1 wherein said plasma torch means is an inductively coupled plasma torch.

10. A method for making silicon thin film solar cell modules comprising:
supporting a substrate, said substrate having an outer surface and an inner surface;
providing a high frequency induction coupled plasma torch comprising a coil, said induction coupled plasma torch being selected positionable along the surface area of said inner surface of said substrate;
introducing a plasma gas into said high frequency induction coupled plasma torch to form a plasma within said coil;
injecting at least one reagent chemicals into said high frequency induction coupled plasma torch; and
depositing at least one thin film layer on said inner surface of said substrate, wherein said at least one thin layer comprises said silicon thin film solar cell modules.

11. The method for making silicon thin film solar cell modules of claim 10, wherein said depositing at least one thin film layer further comprises:
reciprocating the substrate back and forth along its longitudinal axis relative to said high frequency induction coupled plasma torch.

12. The method for making silicon thin film solar cell modules of claim 10, wherein said depositing at least one thin film layer further comprises:
rotating the substrate about its longitudinal axis relative to said high frequency induction coupled plasma torch.

13. The method for making silicon thin film solar cell modules of claim 10, wherein said depositing at least one thin film layer further comprises:
scribing said at least one thin film layer for producing interconnections among said silicon thin film solar cell modules.

14. The method for making silicon thin film solar cell modules of claim 10, further comprising:
injecting one of a liquid and gas on the outer surface to control the temperature of the substrate.

15. The method for making silicon thin film solar cell modules of claim 10, further comprising:
depositing a thin layer of molybdenum on said inner surface prior to deposition of said at least one thin film layer.

16. The method for making silicon thin film solar cell modules of claim 10, wherein said depositing at least one thin film layer further comprises:
depositing a n-type doped silicon layer on said inner surface of said substrate.

17. The method for making silicon thin film solar cell modules of claim 10, wherein said depositing at least one thin film layer further comprises:
depositing a i-type doped silicon layer on said inner surface of said substrate.

18. The method for making silicon thin film solar cell modules of claim 10, wherein said depositing at least one thin film layer further comprises:
depositing a p-type doped silicon layer on said inner surface of said substrate.

19. The method for making silicon thin film solar cell modules of claim 10, wherein said at least one reagent chemicals is selected from the group consisting of SiCl₄, SiH₄, SiHCl₃, SiF₄, silicon containing compounds, PH₃, B₂H₆, GeH₄, GeCl₄, GeF₄, and germanium containing compounds.

20. The method for making silicon thin film solar cell modules of claim 10, wherein said reagent chemicals are in a form selected from the group consisting of a gas, vapor, aerosol, small particle, and powder.

21. The method for making silicon thin film solar cell modules of claim 10, wherein said depositing at least one thin film layer further comprises:
depositing a thin film layer of transparent conductive metal oxide on said inner surface of said substrate after the deposition of said at least one thin film layer.

22. The method for making silicon thin film solar cell modules of claim 21, wherein said transparent conductive metal oxide is an oxide selected from the group consisting of indium, tin, and zinc.

23. The method for making silicon thin film solar cell modules of claim 10, wherein said plasma gas is selected from the group consisting of helium, neon, argon, hydrogen, and mixtures thereof.

24. The method for making silicon thin film solar cell modules of claim 10, wherein said silicon thin film solar cell modules are selected from the group consisting of p-i-n and n-i-p type layered structures.

25. The method for making silicon thin film solar cell modules of claim 10, further comprising:
cutting said solar cell modules into smaller portions to be mounted on a substrate for producing a solar cell panel.

26. A silicon thin film photovoltaic panel comprising:
a plurality of concave cylindrical portions of a silicon thin film solar cell module located adjacent to each other, and
interconnections between said plurality of concave cylindrical portions of a silicon thin film solar cell module for conducting electricity.

27. The silicon thin film photovoltaic panel of claim 26, wherein said silicon thin film solar cell modules are selected from the group consisting of p-i-n and n-i-p type layered structures.

28. A silicon thin film photovoltaic panel comprising:
a plurality of disk portions of a silicon thin film solar cell module located adjacent to each other; and
interconnections between said plurality of disk portions of a silicon thin film solar cell module for conducting electricity.

29. The silicon thin film photovoltaic panel of claim 28, wherein said silicon thin film solar cell modules are selected from the group consisting of p-i-n and n-i-p type layered structures.
